(19) United States
(12) Patent Application Publication
(10) Pub. No.: US 2026/0319013 A1
(43) Pub. Date: Oct. 15, 2026

(54) SYSTEM FOR DIAGNOSING BATTERY OF VEHICLE AND METHOD THEREFOR

(71) Applicants: Hyundai Motor Company, Seoul (KR); Kia Corporation, Seoul (KR)

(72) Inventors: Yo Han BAEK, Hwaseong-Si (KR); Bo Hyun LEE, Hwaseong-Si (KR)

(21) Appl. No.: 19/395,599

(22) Filed: Nov. 20, 2025

(30) Foreign Application Priority Data
Apr. 9, 2025 (KR) 10-2025-0046330

(51) Int. Cl. G01R 31/392; B60L 3/00; B60L 58/12; G01R 31/3835; G01R 31/396; H01M 10/42; H01M 10/48; H01M 50/249

(52) U.S. Cl. CPC G01R 31/392; B60L 3/0046; B60L 58/12; G01R 31/3835; G01R 31/396; H01M 10/425; H01M 10/48; H01M 50/249; B60L 2240/547; H01M 2010/4271; H01M 2220/20

(57) ABSTRACT

Disclosed is a system for diagnosing a battery of a vehicle. The system includes a high voltage battery installed in the vehicle to supply power, a power converter installed in the vehicle to convert direct current (DC) power supplied to the high voltage battery, and a battery diagnostic apparatus connected with the power converter to discharge the high voltage battery and diagnose a state of the high voltage battery.

### CROSS-REFERENCE TO RELATED APPLICATION

This application claims the benefit of priority to Korean Patent Application No. 10-2025-0046330, filed in the Korean Intellectual Property Office on Apr.09, 2025, the entire contents of which are incorporated herein by reference.

### TECHNICAL FIELD

The present disclosure relates to a system for diagnosing a battery of a vehicle and a method therefor, and more particularly, relates to technologies for diagnosing whether the battery of the vehicle is abnormal and a current state of the battery.

### BACKGROUND

The matters described in this Background section are only for enhancement of understanding of the background of the disclosure, and should not be taken as acknowledgment that they correspond to prior art already known to those skilled in the art.

A vehicle which uses electric energy as a power source, for example, an electric vehicle (EV) or a hybrid electric vehicle, is loaded with a battery which stores and outputs electric energy. In general, the battery may be an 800V high voltage battery. The vehicle may include a plurality of battery modules. Each of the battery modules may be composed of a plurality of battery cells. Such a battery cell converts chemical energy into electrical energy to supply the electrical energy (discharging) or converts electrical energy supplied from the outside into chemical energy to store the chemical energy (charging).

To diagnose whether the high voltage battery is abnormal, a battery management system (BMS) may be provided in a vehicle. The BMS may determine whether the battery is abnormal based on sensor data and a diagnostic condition at a diagnostic time point. It may be difficult for the BMS to set a diagnostic condition. Particularly, the BMS may be unable to diagnose a defect of the battery, which may cause a fatal event (e.g., fire or the like). Furthermore, even if the vehicle is stocked at a repair shop if abnormality occurs in the battery of the vehicle, the battery may be diagnosed using only past event data and data at a diagnostic time point even in the repair shop. Thus, to the BMS may not be able to perform a diagnosis with effective and high reliability.

A method using a maintenance network, such as Bluehands, may address the shortcomings of the BMS, but an entry barrier is large for a personal business owner. An 800V high voltage charging/discharging facility among pieces of actual measurement equipment for diagnosing the battery may involve large management cost (e.g., unit cost, installation cost, an installation space, or operational manpower, etc.).

A technology capable of addressing the above-mentioned problem and efficiently diagnosing in advance whether a battery of a vehicle is abnormal is considered.

### SUMMARY

The present disclosure has been made to solve the above-mentioned problems occurring in the prior art while advantages achieved by the prior art are maintained intact.

An example of the present disclosure provides an apparatus for diagnosing whether a battery of a vehicle is abnormal and a current state of the battery and a method therefor.

Another example of the present disclosure provides an apparatus for diagnosing a battery of a vehicle at a low cost using an inverter provided in the vehicle and a method therefor.

The technical problems to be solved by the present disclosure are not limited to the aforementioned problems, and any other technical problems not mentioned herein will be clearly understood from the following description by those skilled in the art to which the present disclosure pertains.

According to the present disclosure, a system for a vehicle may comprise a battery installed in the vehicle and configured to supply power to the vehicle, a power converter installed in the vehicle and configured to convert direct current (DC) power of the battery to first converted power for at least one operation of a vehicle part of the vehicle and second converted power for diagnosing the battery, and a battery diagnostic apparatus coupled to the power converter and configured to discharge, via the second converted power being transferred to the battery diagnostic apparatus, the battery, determine a state of the battery based on data associated with the battery obtained during the discharge, and output, based on the determined state of the battery, a signal indicating a diagnosed state of the battery.

The system may further include that the battery diagnostic apparatus may comprise a load, when coupled to the power converter, configured to discharge the battery based on at least one discharge mode, wherein the load may comprise at least one resistor and at least one relay, a communication interface configured to transmit and receive data associated with the battery, and a processor circuit configured to control operations of the power converter and the load and determine the state of the battery based on at least one diagnostic mode.

The system may further include that the battery diagnostic apparatus may comprise a human machine interface (HMI) configured to receive the at least one diagnostic mode and the at least one discharge mode, wherein the at least one diagnostic mode and the at least one discharge mode are configured to be selected by a user, and output the determined state of the battery.

The system may further include that the power converter may comprise at least one switch and at least one diode, and the at least one switch and the at least one diode may be configured to operate the power converter based on the at least one discharge mode.

The system may further include that the processor circuit may be configured to transmit a voltage profile and a current profile for a charge voltage to the vehicle, based on the vehicle being coupled with the battery diagnostic apparatus.

The system may further include that the processor circuit may be configured to control an operation of the at least one relay to set a current flow path for the load, and control application of the charge voltage to the at least one resistor via the current flow path.

The system may further include that the charge voltage may be applied from the battery to the at least one resistor via the current flow path, and the battery may be discharged via the at least one resistor.

The system may further include that the at least one discharge mode may comprise a first discharge mode in which a first charge voltage is applied to the at least one resistor and the battery is discharged while a constant voltage is applied to the at least one resistor, a second discharge mode in which a second charge voltage is applied to the at least one resistor and the battery is discharged while a current flowing in the at least one resistor is reduced, and a third discharge mode in which the first charge voltage is applied to the at least one resistor and the battery is discharged while the first charge voltage applied to the at least one resistor is reduced and a constant current flows in the at least one resistor, wherein the first charge voltage is less than the second charge voltage.

The system may further include that the second charge voltage may be a rated voltage of the battery, and the second discharge mode may be controlled by an operation of the at least one switch and the at least one diode.

The system may further include that the at least one diagnostic mode may be determined based on a preset discharge condition of the battery, a preset rest time of the battery, and a preset state of charge (SOC) of the battery.

According to the present disclosure, a method performed by a system for a vehicle may comprise supplying, from a battery via a power converter installed in the vehicle, first power to the vehicle, based on coupling of a battery diagnostic apparatus to the power converter, converting, by the power converter installed in the vehicle, direct current (DC) power of the battery to second power for diagnosing the battery, discharging, via the power converter, the battery using the second power, determining a state of the battery based on data associated with the battery obtained during the discharging, and outputting, based on the determined state of the battery, a signal indicating a diagnosed state of the battery.

According to the present disclosure, a battery diagnostic apparatus for a vehicle may comprise a load configured to be coupled with a battery of the vehicle through a power converter installed in the vehicle, the load being configured to discharge the battery under at least one of a constant power mode, a constant resistance mode, or a constant current mode, a communication interface configured to exchange data with the vehicle during the discharge of the battery, wherein the data may comprise at least one of voltage of the battery, current of the battery, temperature of the battery, or state of charge of the battery, a charge port configured to connect the battery diagnostic apparatus to the vehicle and provide, during diagnosis, a discharge path for the battery, a human machine interface configured to receive a selection of at least one diagnostic mode, wherein the at least one diagnostic mode may comprise a manual discharge mode, a preprocessing mode, a state-of-charge monitoring mode, a state diagnostic mode, or a life diagnostic mode, and a processor circuit configured to control the power converter and the load to discharge the battery based on the received selection of the at least one diagnostic mode and output, based on processing the data, diagnostic results indicating whether the battery is abnormal and a current state of the battery.

The battery diagnostic apparatus may further include that the processor circuit may be configured to, in the constant power mode, control the load by applying a constant voltage to the load during discharge of the battery.

The battery diagnostic apparatus may further include that the processor circuit may be configured to, in the state-of-charge monitoring mode, identify a voltage deviation among battery cells of the battery and determine, based on the identified voltage deviation, the diagnostic results.

The battery diagnostic apparatus may further include that the processor circuit may be configured to, in the preprocessing mode, discharge the battery to a preset state of charge of the battery before executing another one of the at least one diagnostic mode.

The battery diagnostic apparatus may further include that the processor circuit may be configured to, in the life diagnostic mode, determine a deterioration degree of the battery based on a change rate of the state of charge during the discharge.

The battery diagnostic apparatus may further include that the processor circuit may be configured to, in the manual discharge mode, control the discharge of the battery based on discharge conditions and rest times input by a user via the human machine interface.

The battery diagnostic apparatus may further include that the processor circuit may be configured to, in the state diagnostic mode, determine whether the battery is abnormal based on a temperature deviation of the battery during the discharge.

### BRIEF DESCRIPTION OF THE DRAWINGS

The above and other objects, features and advantages of the present disclosure will be more apparent from the following detailed description taken in conjunction with the accompanying drawings:

FIG. 1 shows an example of a system for diagnosing a battery of a vehicle;

FIG. 2 shows an example of a configuration of a system for diagnosing a battery of a vehicle;

FIG. 3 is an example of a battery diagnostic apparatus;

FIG. 4 is an example of a circuit for a system for diagnosing a battery of a vehicle;

FIG. 5 shows an example of a method for diagnosing a battery of a vehicle;

FIG. 6, FIG. 7, FIG. 8, FIG. 9, and FIG. 10 are show an example of at least one diagnostic mode; and

FIG. 11 shows an example of a computing system.

### DETAILED DESCRIPTION

Hereinafter, some examples of the present disclosure will be described in detail with reference to the exemplary drawings. In adding the reference numerals to the components of each drawing, it should be noted that the identical component is designated by the identical numerals even when they are displayed on other drawings. Further, in describing the example of the present disclosure, a detailed description of well-known features or functions will be ruled out in order not to unnecessarily obscure the gist of the present disclosure.

In describing the components of the example of the present disclosure, terms such as first, second, “A”, “B”, (a), (b), and the like may be used. These terms are only used to distinguish one component from another component, but do not limit the corresponding components irrespective of the order or priority of the corresponding components. Furthermore, unless otherwise defined, all terms including technical and scientific terms used herein have the same meaning as being generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

The term “module” or “unit” used in the specification means a software and/or hardware component, and the “module” or “unit” performs certain operations/functions/roles. However, the “module” or “unit” is not construed as being limited to software or hardware. The “module” or “unit” may be configured to be in an addressable storage medium or to execute one or more processors. Therefore, as an example, the “module” or “unit” may include at least one of components such as software components, object-oriented software components, class components, and task components, processes, functions, attributes, procedures, sub-routines, segments of program codes, drivers, firmware, micro-codes, circuits, data, databases, data structures, tables, arrays, or variables. Functions provided in the components, “modules”, or “units” may be combined into a smaller number of components, “modules”, or “units” or further divided into additional components, “modules”, or “units”.

In the present disclosure, the “module” or “unit” may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. Moreover, the “memory” should be widely construed to include any electronic component capable of storing electronic information. The “memory” may refer to various types of processor-readable medium such as a random access memory (RAM), a read only memory (ROM), a non-volatile random access memory (NVRAM), a programmable read only memory (PROM), an erasable programmable read only memory (EPROM), an electrically erasable programmable read only memory (EEPROM), a flash memory, a magnetic or optical data storage device, and registers. When the processor can read information from a memory and/or record the information in the memory, the memory may be in a state of electronic communication with a processor. Memory integrated into a processor is in a state of electronic communication with the processor.

The one or more features described herein may be provided as a computer program stored in a computer-readable recording medium in order to be executed on a computer. The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a CD-ROM or a DVD, magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

In a hardware implementation, processing units used for performing the techniques may be implemented within one or more ASICs, DSPs, digital signal processing devices, programmable logic devices, field-programmable gate arrays, processors, controllers, microcontrollers, microprocessors, electronic devices, or computers or combinations thereof designed to perform the functions described in the present disclosure

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as "A, B, or C", "at least one of A, B, and C", "at least one of A, B, or C", etc. as used herein may mean each listed item or all possible combinations of the listed items. For example, "at least one of A or B" may refer to (1) at least one A; (2) at least one B; or (3) at least one A and at least one B.

An automation level of an autonomous driving vehicle may be classified as follows, according to the American Society of Automotive Engineers (SAE). At autonomous driving level 0, the SAE classification standard may correspond to “no automation,” in which an autonomous driving system is temporarily involved in emergency situations (e.g., automatic emergency braking) and/or provides warnings only (e.g., blind spot warning, lane departure warning, etc.), and a driver is expected to operate the vehicle. At autonomous driving level 1, the SAE classification standard may correspond to “driver assistance,” in which the system performs some driving functions (e.g., steering, acceleration, brake, lane centering, adaptive cruise control, etc.) while the driver operates the vehicle in a normal operation section, and the driver is expected to determine an operation state and/or timing of the system, perform other driving functions, and cope with (e.g., resolve) emergency situations. At autonomous driving level 2, the SAE classification standard may correspond to “partial automation,” in which the system performs steering, acceleration, and/or braking under the supervision of the driver, and the driver is expected to determine an operation state and/or timing of the system, perform other driving functions, and cope with (e.g., resolve) emergency situations. At autonomous driving level 3, the SAE classification standard may correspond to “conditional automation,” in which the system drives the vehicle (e.g., performs driving functions such as steering, acceleration, and/or braking) under limited conditions but transfer driving control to the driver when the required conditions are not met, and the driver is expected to determine an operation state and/or timing of the system, and take over control in emergency situations but do not otherwise operate the vehicle (e.g., steer, accelerate, and/or brake). At autonomous driving level 4, the SAE classification standard may correspond to “high automation,” in which the system performs all driving functions, and the driver is expected to take control of the vehicle only in emergency situations. At autonomous driving level 5, the SAE classification standard may correspond to “full automation,” in which the system performs full driving functions without any aid from the driver including in emergency situations, and the driver is not expected to perform any driving functions other than determining the operating state of the system. Although the present disclosure may apply the SAE classification standard for autonomous driving classification, other classification methods and/or algorithms may be used in one or more configurations described herein.

One or more features associated with autonomous driving control may be activated based on configured autonomous driving control setting(s) (e.g., based on at least one of: an autonomous driving classification, a selection of an autonomous driving level for a vehicle, etc.). Based on the feature of discharge-based battery diagnostics using the vehicle inverter and a resistor load described herein, an operation of the vehicle may be controlled. For example, when the diagnostic apparatus determines, through the inverter and resistor load, that the battery condition indicates reduced capacity, abnormal resistance, or degraded health, the autonomous driving control may be adjusted to reduce energy-intensive functions (e.g., limiting rapid acceleration, constraining maximum speed, or reducing reliance on redundant sensor fusion). Conversely, when diagnostic results confirm sufficient battery performance, enhanced autonomous driving functions may be enabled (e.g., full-speed cruise control, high-frequency sensor sampling, or extended operation of safety assist systems). The vehicle control may therefore include various operational controls associated with the vehicle (e.g., autonomous driving control, sensor control, braking control, braking time control, acceleration control, acceleration change rate control, alarm timing control, forward collision warning time control, etc.), all dynamically adapted according to diagnostic data from the battery obtained through the inverter and resistor load.

One or more auxiliary devices (e.g., engine brake, exhaust brake, hydraulic retarder, electric retarder, regenerative brake, etc.) may also be controlled based on the feature of discharge-based battery diagnostics using the vehicle inverter and a resistor load described herein. For instance, when diagnostic results obtained through the inverter and resistor load indicate reduced battery capacity or abnormal operating states, the processor may increase reliance on mechanical auxiliary braking devices (e.g., engine brake or hydraulic retarder) while limiting regenerative braking to avoid overloading the degraded battery. Conversely, when diagnostic results confirm sufficient battery health, regenerative braking may be prioritized to maximize energy recovery and efficiency. Thus, the control of auxiliary devices may dynamically adapt to discharge-based diagnostic assessments of the battery, ensuring safe braking performance while balancing energy conservation and system reliability.

One or more communication devices (e.g., a modem, a network adapter, a radio transceiver, an antenna, etc.) that are capable of communicating via one or more wired or wireless communication protocols, such as Ethernet, Wi-Fi, near-field communication (NFC), Bluetooth, Long-Term Evolution (LTE), 5G New Radio (NR), or vehicle-to-everything (V2X), may also be controlled based on the feature of discharge-based battery diagnostics using the vehicle inverter and a resistor load described herein. For instance, when the battery diagnostic apparatus determines, through the inverter and resistor load, that the battery has reduced capacity or abnormal operating conditions, the processor may limit or prioritize communication functions to conserve energy (e.g., restricting non-essential infotainment data transfer while maintaining V2X safety communication). Conversely, if diagnostic results confirm sufficient battery health, higher-bandwidth communication services may be enabled (e.g., vehicle-to-cloud diagnostics upload, over-the-air software updates, or high-rate V2X messaging). Thus, the control of communication devices may dynamically adapt to discharge-based diagnostic results, ensuring both safe vehicle operation and efficient use of available energy resources.

Minimum risk maneuver (MRM) operation(s) may also be controlled, for example, based on the feature of discharge-based battery diagnostics using the vehicle inverter and a resistor load described herein. A minimal risk maneuvering operation (e.g., a minimal risk maneuver, a minimum risk maneuver) may be a maneuvering operation of a vehicle to minimize a risk of collision with surrounding vehicles in order to reach a lowered (e.g., minimum) risk state. In particular, the diagnostic apparatus may determine the state of the battery through the inverter and resistor load and provide control inputs for MRM operations. For example, if diagnostic results indicate reduced battery capacity, increased internal resistance, or abnormal voltage deviation, the vehicle may initiate an MRM that prioritizes energy-efficient maneuvers (e.g., reduced acceleration, limited lane changes, or gradual deceleration) to safely reach a stop. A minimal risk maneuver may thus be activated during autonomous driving of the vehicle when a driver is unable to respond to a request to intervene, and may further adapt its control profile according to the diagnostic results obtained via discharge-based testing of the battery. During the minimal risk maneuver, one or more processors of the vehicle may control a driving operation of the vehicle for a set period of time, ensuring that battery limitations identified through the inverter and resistor load are considered in selecting safe and energy-appropriate MRM strategies.

Biased driving operation(s) may also be controlled, for example, based on the feature of discharge-based battery diagnostics using the vehicle inverter and a resistor load described herein. A driving control apparatus may perform a biased driving control that adjusts vehicle behavior according to the diagnostic state of the battery. To perform a biased driving operation, the driving control apparatus may control the vehicle to drive in a lane with an intentional offset or altered lateral distance depending on available battery capacity or detected deterioration identified through the discharge-based diagnostics. For example, when the battery diagnostic apparatus determines, through the inverter and resistor load, that the battery has reduced capacity or increased resistance, the vehicle may be controlled to favor a lane position that minimizes energy consumption (e.g., smoother lane keeping to reduce steering effort). The driving control apparatus may identify or determine a biased target lateral distance for biased driving control based on the diagnostic data. For instance, if battery health indicates a reduced margin for high-power maneuvers, the vehicle may adopt a biased lateral distance that maintains greater separation from adjacent lanes or vehicles, thereby reducing the likelihood of abrupt accelerations or emergency steering. This adjustment may improve vehicle stability, safety, and performance under varying driving conditions while aligning with available battery resources. For example, during a lane change, the driving control system may bias the lateral distance to keep a safer gap from adjacent vehicles when the battery diagnostic results obtained via discharge-based testing indicate limited output capability, considering factors such as vehicle speed, road conditions, and the presence of obstacles.

One or more sensors (e.g., IMU sensors, camera, LIDAR, RADAR, blind spot monitoring sensor, line departure warning sensor, parking sensor, light sensor, rain sensor, traction control sensor, anti-lock braking system sensor, tire pressure monitoring sensor, seatbelt sensor, airbag sensor, fuel sensor, emission sensor, throttle position sensor, inverter, converter, motor controller, power distribution unit, high-voltage wiring and connectors, auxiliary power modules, charging interface, etc.) may also be controlled, for example, based on the feature of discharge-based battery diagnostics using the vehicle inverter and a resistor load described herein. For instance, when the battery diagnostic apparatus determines, through the inverter and the resistor load, that battery health or available capacity is reduced, certain sensors may be prioritized or deactivated to conserve power (e.g., non-essential sensors such as parking sensors or comfort-related sensors). Conversely, if diagnostic results confirm sufficient battery capacity, additional sensors may be activated for advanced autonomous driving functions (e.g., enabling full sensor fusion with LIDAR, RADAR, and cameras). An operation control for autonomous driving of the vehicle may therefore adaptively use sensor data depending on the diagnostic results, and may include various driving control functions by the vehicle control device (e.g., acceleration, deceleration, steering control, gear shifting control, braking system control, traction control, stability control, cruise control, lane keeping assist control, collision avoidance system control, emergency brake assistance control, traffic sign recognition control, adaptive headlight control, etc.).

An autonomous driving level and/or autonomous driving activation or deactivation may also be controlled based on the feature of discharge-based battery diagnostics using the vehicle inverter and a resistor load described herein. A driving control apparatus may perform an autonomous driving level control (e.g., a change of an autonomous driving level, a change of a required user attentiveness, etc.) or cause deactivation of an autonomous driving operation. For example, when the battery diagnostic apparatus determines, through the inverter and the resistor load, that the battery state indicates reduced capacity or abnormal performance, the autonomous driving level may be automatically reduced to limit power demand. Alternatively, the apparatus may deactivate autonomous driving if diagnostic data suggests that battery reliability is insufficient for safe autonomous operation. By changing the required user attentiveness, the driver may be prompted to place his/her hands on the steering wheel more frequently (e.g., at least once in a threshold time period, such as five seconds, 30 seconds, one minute, etc.) or may be required to look ahead more often (e.g., at least once in a threshold time period, such as five seconds, 30 seconds, one minute, etc.). By dynamically linking the diagnostic results of the discharge-based battery diagnostics to the autonomous driving level, the vehicle can ensure both safe driving and efficient use of battery resources.

According to the present disclosure, a system and method are provided for diagnosing a battery of a vehicle in a cost-effective and reliable manner. A battery diagnostic apparatus may be connected to the vehicle through a charge port and may cooperate with a power converter, such as an inverter, already installed in the vehicle. By selectively discharging the battery under controlled conditions and monitoring voltage, current, temperature, and state of charge, the system may determine whether the battery is abnormal and assess its current state and remaining life. Various discharge modes, including constant power, constant resistance, and constant current, may be applied, and diagnostic modes such as manual discharge, preprocessing, state-of-charge monitoring, state diagnosis, and life diagnosis may be executed. Results may be output to a user through a human machine interface, thereby improving the accessibility and convenience of battery maintenance, while reducing equipment cost and enhancing safety by detecting potential defects in advance.

According to the present disclosure, the battery diagnostic apparatus may be configured to perform real-time monitoring of the battery when coupled to the vehicle and may optimize vehicle operation in real time (e.g., adjusting torque limits, activating an eco-driving mode, or restricting high-power functions). The apparatus may be detachable and may store the monitored real-time data (e.g., voltage profiles, current profiles, or temperature records), for example, to detect a battery cell anomaly (e.g., abnormal cell voltage deviation) and enable a safe operation mode of the vehicle (e.g., limiting acceleration or reducing maximum speed). For example, the apparatus may determine that a state of charge (SOC) of the battery is low and cause the vehicle to operate in a low power mode (e.g., restricting use of auxiliary systems such as air conditioning or heating). The apparatus may further be inspected and then coupled to another vehicle to quickly optimize operation of the other vehicle. The battery diagnostic apparatus may also be implemented in a portable device (e.g., a handheld diagnostic tool or a tablet-based device) and, when coupled to the vehicle, may diagnose the battery condition and enhance or optimize one or more operations of the vehicle in real time (e.g., power management, thermal management, or charging operations performed during highway driving, stop-and-go traffic, or while the vehicle is parked).

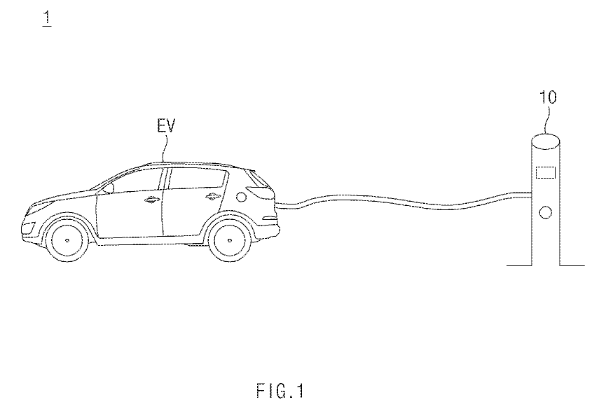

Hereinafter, examples of the present disclosure will be described in detail with reference to FIGS. 1 to 11.

FIG. 1 shows an example of a system 1 for diagnosing a battery of a vehicle according to an example of the present disclosure.

Referring to FIG. 1, the system 1 for diagnosing the battery may include a vehicle EV and a battery diagnostic apparatus 10.

Herein, it is assumed that the vehicle EV is a vehicle which drives by driving an electric motor using a high voltage battery. Thus, the vehicle EV may include a hybrid electric vehicle (HEV), an electric vehicle (EV), a plug-in hybrid electric vehicle (PHEV), a fuel cell electric vehicle (FCEV), or another type of electric vehicle (e.g., a range-extended EV, a trolley bus, an electric forklift, or an electric motorcycle, etc.).

To diagnose a state of the high voltage battery of the vehicle EV, maintenance work for demounting various controllers, an inverter, a cable, the high voltage battery, or other related components (e.g., sensors, cooling modules, or wiring harnesses, etc.) may be involved. Thus, after the high voltage battery is discharged for safety before the maintenance work of the vehicle EV, the maintenance work may proceed. For example, the high voltage battery of the vehicle EV may be discharged using equipment including an electronic load (e.g., a programmable DC load, a resistive load bank, or a regenerative load system, etc.).

The battery diagnostic apparatus 10 may be connected via a coupler (e.g., a charging port, a charging connector, etc.), together with a charger for charging the high voltage battery of the vehicle EV. The coupler may be a charging cable for connecting the vehicle EV with the charger, which may refer to a charging facility including a connection port connector and a charging connection port inlet of the charger (e.g., a CCS connector, a CHAdeMO connector, or a Type 2 connector, etc.).

If the battery diagnostic apparatus 10 is connected with the vehicle EV via the coupler, it may receive data of the high voltage battery 20 at a predetermined period from the vehicle EV (e.g., voltage, current, temperature, or state-of-charge data, etc.).

The battery diagnostic apparatus 10 may discharge the high voltage battery 20 and may diagnose a state of the high voltage battery 20 based on data of the high voltage battery 20, which is measured while discharging the high voltage battery 20. Thus, the battery diagnostic apparatus 10 may include fault diagnostic equipment of the vehicle EV, such as global diagnostic system (GDS) diagnostics (e.g., onboard diagnostics tools, dealer diagnostic platforms, or remote telematics-based diagnostics, etc.).

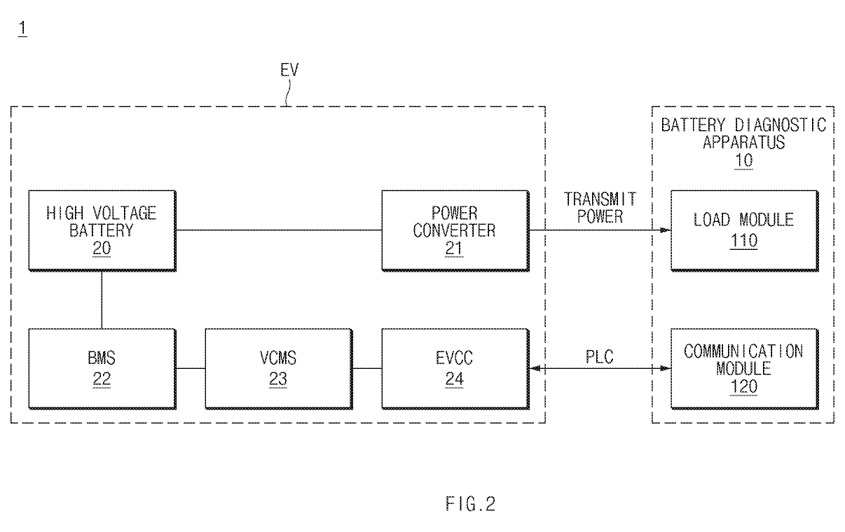

FIG. 2 shows an example of a configuration of a system 1 for diagnosing a battery of a vehicle.

A vehicle EV may include a high voltage battery 20, a power converter 21, a battery management system (BMS) 22, a vehicle charging management system (VCMS) 23, and an electric vehicle communication controller (EVCC) 24.

A battery diagnostic apparatus 10 may include a load module 110 and a communication module 120.

In an example, the high voltage battery 20 may be installed in the vehicle EV to supply power to the vehicle EV. For example, the high voltage battery 20 may be formed in a structure in which a plurality of battery cells are connected in series or in parallel with each other. The high voltage battery 20 may supply driving power of a driver of the vehicle EV, such as a motor and/or a generator (e.g., a traction motor, an auxiliary motor, or a starter-generator, etc.).

A high voltage may be stored in the high voltage battery 20 to supply the driving power to the driver. Furthermore, the high voltage battery 20 may be charged with a voltage generated by the motor upon regenerative breaking. If the high voltage battery 20 is connected with the charger, it may be charged by a voltage and a current supplied from the charger. Herein, a rated voltage of the high voltage battery 20 may be assumed as, but not limited to, 800 V (e.g., 400 V, 600 V, or 1000 V systems may also be used, etc.).

In an example, the power converter 21 may be installed in the vehicle EV to convert direct current (DC) power supplied to the high voltage battery 20 into alternating current (AC) power. For example, the power converter 21 may convert DC power supplied from the high voltage battery 20 into AC power to drive the motor of the vehicle EV. Herein, the power converter 21 may include a multi-inverter (e.g., a 3-phase inverter, a dual-inverter, or a modular inverter, etc.). Alternatively, if the vehicle EV is connected with the charger, the power converter 21 may convert a magnitude of DC power supplied to the high voltage battery 20. The power converter 21 may convert the high voltage battery 20 with the rated voltage of 800 V into a rated voltage of 400 V to perform fast charging.

The power converter 21 may include at least one switching element and at least one diode. The power converter 21 may include, but is not limited to, a circuit structure of a 3-phase inverter. For example, the power converter 21 may convert a DC voltage of the high voltage battery 20 into a 3-phase AC voltage to drive the motor. The high voltage battery 20 may be discharged by the driving of the motor (e.g., during acceleration, hill climbing, or sustained highway driving, etc.).

If the high voltage battery 20 should be discharged to diagnose a state of the high voltage battery 20 of the vehicle EV, the power converter 21 and the battery diagnostic apparatus 10 may be connected with each other. For example, if the battery diagnostic apparatus 10 and the vehicle EV are connected with each other via the coupler, the high voltage battery 20 may transmit power to the load module 110 via the power converter 21.

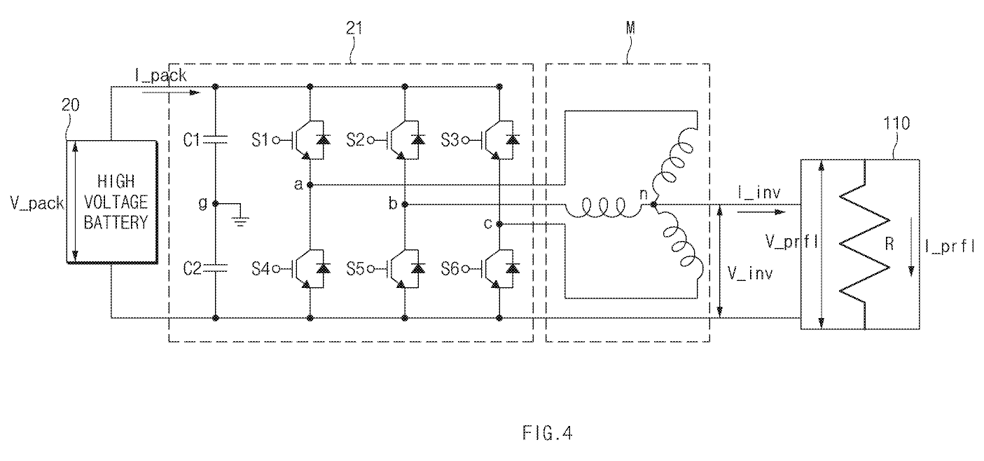

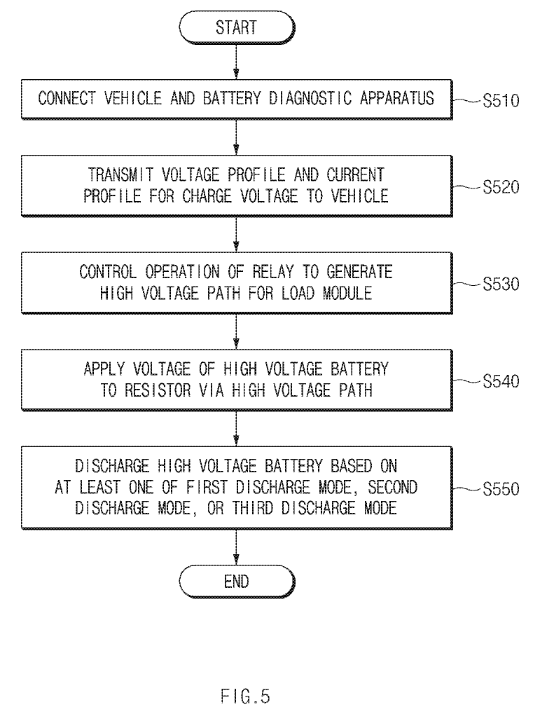

A detailed configuration of the power converter 21 will be described in detail below in a description of FIG. 4.

In an example, the BMS 22 may be a battery management system, which may detect a current and a voltage of each of battery cells in an operation area of the high voltage battery 20. The BMS 22 may manage a state of charge (SOC) including cell balancing of the high voltage battery 20 or the like based on the detected result. Herein, the SOC may refer to a state of charge of the high voltage battery 20 and may be represented as a percentage (%) by dividing a battery capacity capable of being currently used by the entire capacity to indicate a remaining battery capacity. In general, the BMS 22 may calculate an SOC to optimize performance and life of the high voltage battery 20. At this time, the BMS 22 may calculate an SOC based on a voltage profile of the high voltage battery 20. Alternatively, the BMS 22 may measure a current of the high voltage battery 20 and may integrate the measured current over time to calculate an SOC. However, this is only one example, but not limited thereto (e.g., SOC may also be estimated using Kalman filters, neural networks, or equivalent algorithms, etc.).

In an example, the VCMS 23 may transmit and receive data with the BMS 22 and the EVCC 24. The VCMS 23 may control a charge and discharge voltage of the high voltage battery 20 to prevent life from being shortened as the charge and discharge voltage is over-discharged to less than or equal to a limit voltage or is over-charged to greater than or equal to the limit voltage (e.g., lower than 2.5 V/cell or higher than 4.2 V/cell, etc.).

In an example, the EVCC 24 may transmit and receive data with the VCMS 23 and the battery diagnostic apparatus 10. Thus, the EVCC 24 may include a power line communication (PLC) modem. For example, the EVCC 24 may perform PLC with the communication module 120 of the battery diagnostic apparatus 10 in real time via the charging cable to transmit and receive data. Thus, the communication module 120 may also include a PLC modem. Furthermore, a standard charging communication protocol between the EVCC 24 and the communication module 120 may include a standard charging communication protocol (e.g., ISO15118, a fast charging protocol, or the like) between the EVCC 24 and the charger.

The EVCC 24 may prevent over-charging of the vehicle EV in advance and may early detect a symptom of the high voltage battery 20 (e.g., abnormal temperature rise, abnormal voltage deviation, or unexpected current spikes, etc.).

In an example, the load module 110 of the battery diagnostic apparatus 10 may discharge the high voltage battery 20. Thereafter, the battery diagnostic apparatus 10 may diagnose the high voltage battery 20 based on data of the high voltage battery 20, which is measured while discharging the high voltage battery 20. Thus, the battery diagnostic apparatus 10 may include GDS diagnostics. Herein, the GDS diagnostics may be equipment for diagnosing a breakdown in the vehicle EV, which may be configured by being connected with the load module 110. Alternatively, the GDS diagnostics may be configured as a device independent of the load module 110 to be included in the battery diagnostic apparatus 10. At this time, the load module 110 and the GDS diagnostics may transmit and receive data via separate communication. However, this is only one example, but not limited thereto (e.g., other diagnostic interfaces may include OBD-II, UDS, or proprietary CAN-based tools, etc.).

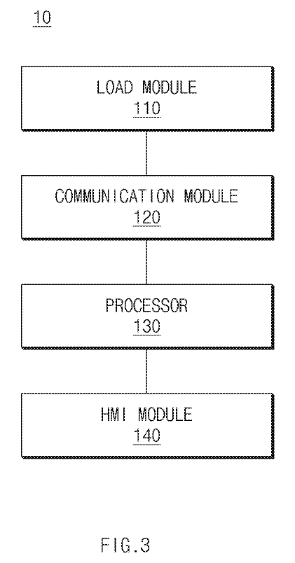

A detailed configuration of the battery diagnostic apparatus 10 will be described in detail below in a description of FIG. 3.

As described above, the system 1 for diagnosing the battery of the vehicle according to the present disclosure may use the inverter provided in the vehicle to improve the reliability of the battery diagnostic apparatus at a low cost. Furthermore, the system 1 for diagnosing the battery may diagnose whether the battery of the vehicle is abnormal to prevent safety accidents (e.g., thermal runaway, fire, or sudden shutdown, etc.). Furthermore, the system 1 for diagnosing the battery is able to diagnose the battery of the vehicle at a low cost to improve the accessibility and convenience of the user upon the vehicle maintenance (e.g., by allowing remote diagnostics, simplified service procedures, or reduced downtime, etc.).

FIG. 3 is an example of a battery diagnostic apparatus 10 according to an example of the present disclosure. FIG. 4 is an example of a circuit for a system 1 for diagnosing a battery of a vehicle according to an example of the present disclosure.

Referring to FIG. 3, a battery diagnostic apparatus 10 may include a load module 110, a communication module 120, a processor 130, and a human machine interface (HMI) module 140 (e.g., a touchscreen, physical buttons, or a voice input interface, etc.).

In an example, the load module 110 may include at least one resistor and at least one relay.

In an example, the communication module 120 may transmit and receive data of a high voltage battery 20. For example, if the battery diagnostic apparatus 10 is connected with a vehicle EV via a coupler, the communication module 120 may communicate with an EVCC of the vehicle EV to transmit and receive data. At this time, the battery diagnostic apparatus 10 may receive data of the high voltage battery 20 at a predetermined period from the EVCC (e.g., every 100 ms, 500 ms, or 1 second, etc.).

In an example, the processor 130 may control operations of a power converter 21 and the load module 110 (e.g., starting, stopping, or switching between diagnostic modes, etc.).

The processor 130 may include a processor of GDS diagnostics. Herein, the GDS diagnostics may be equipment for diagnosing a breakdown in the vehicle EV, which may be configured by being connected with the load module 110. Alternatively, the GDS diagnostics may be configured as a device independent of the load module 110 to be included in the battery diagnostic apparatus 10. At this time, the load module 110 and the GDS diagnostics may transmit and receive data via separate communication (e.g., CAN bus, Ethernet, or wireless link, etc.). However, this is only one example, but not limited thereto.

If the vehicle EV is connected with the battery diagnostic apparatus 10, the processor 130 may transmit a voltage profile and a current profile for a charge voltage to the EVCC. For example, the processor 130 may transmit a command signal for recognizing that the vehicle EV is connected with a charger via the communication module 120. Simultaneously, the processor 130 may transmit a voltage profile and a current profile for the load module 110 to the EVCC. Thereafter, a VCMS of the vehicle EV may receive the above-mentioned command signal from the EVCC and may notify a system (e.g., a vehicle controller unit (VCU), a micro controller unit (MCU), a battery management unit (BMU), or a body control module (BCM), etc.) provided in the vehicle EV that the charger is connected. Thereafter, the VCMS may transmit a control request to the MCU such that the power converter 21 performs a charging operation based on the voltage profile and the current profile of the load module 110. The MCU may control the power converter 21 in response to the control request. Thereafter, the power converter 21 may receive a control signal of the processor 130 via the MCU to control a voltage and a current output according to at least one of a first discharge mode, a second discharge mode, or a third discharge mode (e.g., constant power, constant resistance, or constant current, etc.). However, this is only one example, but not limited thereto.

Next, the processor 130 may control an operation of at least one relay to generate a high voltage path for the load module 110. For example, the processor 130 may control a main relay of the load module 110 and a relay connected with a resistor R to form the high voltage path. Thereafter, the processor 130 may control a charge voltage to be supplied to the resistor R via the high voltage path. Herein, the charge voltage may be, but is not limited to, 400 V or 800 V (e.g., 200 V, 600 V, or 1000 V, etc.).

In other words, a voltage may be applied from the high voltage battery 20 to the resistor R of the load module 110 via the high voltage path. Simultaneously, the high voltage battery 20 may be discharged.

Referring to FIG. 4, the load module 110 may be connected with the power converter 21 to discharge the high voltage battery 20 based on at least one discharge mode. For example, as the voltage of the high voltage battery 20 is applied to a load of the load module 110, that is, the resistor R, the load module 110 may discharge the high voltage battery 20. Herein, the at least one discharge mode may include the first discharge mode, the second discharge mode, and the third discharge mode. At this time, an appropriate voltage may be applied to the resistor R via control of the power converter 21, such that appropriate power is transmitted to the resistor R.

In an example, the power converter 21 may include at least one switching device (S1 to S6). Herein, the switching device (S1 to S6) may include at least one switching element and at least one diode. For example, the switching element may include a power semiconductor. Herein, the power semiconductor may refer to a switching element for converting an electric form, such as a voltage, a current, a frequency, or a direct current/alternating current (DC/AC). Thus, the switching element may include, but is not limited to, at least one of an insulated gate bipolar transistor (IGBT), a metal-oxide-semiconductor field-effect transistor (MOSFET), a thyristor, a gate turn-off thyristor (GTO), or a triode alternating current (TRIAC) (e.g., in single-package, module, or discrete device form, etc.). Furthermore, the at least one diode may be, but is not limited to, an anti-parallel diode (e.g., a fast recovery diode, a Schottky diode, or a silicon carbide diode, etc.).

The switching device (S1 to S6) may be short or open by an ON or OFF control signal based on the control signal output from the processor 130. For example, the switching device (S1 to S6) may receive the control signal of the processor 130 via the MCU and may operate based on at least one discharge mode by the control signal (e.g., constant power, constant resistance, or constant current control, etc.).

The power converter 21 may be connected to each of a motor M and the load module 110. For example, the power converter 21 may be a circuit structure of a 3-phase inverter and may control 3 phases of the motor M. in other words, the switching device (S1 to S6) may operate such that a terminal voltage of each phase of the motor M has a phase difference of 120˚. For example, the direction of a phase current may be controlled according to whether the switching device (S1 to S3) located on an upper end of the power converter 21 is short or whether the switching device (S4 to S6) located on a lower end of the power converter 21 is short. At this time, the power converter 21 may be composed of the switching devices S1 to S6 including 6 switching elements. Two switching elements of the power converter 21 may be connected with one phase of the motor M. Thus, the motor M may operate by a 3-phase AC voltage applied to the power converter 21 to generate a driving force. n shown in FIG. 4 may be a centerpoint of the motor M and g may be ground (GND). In FIG. 4, reference labels a, b, and c denote respective phase connection nodes of the motor M. However, the circuit structure of the power converter 21 shown in FIG. 4 is only one example, but not limited thereto (e.g., other topologies such as a Vienna rectifier, a dual-active bridge, or a matrix converter may also be applied, etc.).

In an example, a voltage V_pack and a current I_pack applied to the high voltage battery 20 may be applied to the motor M via the power converter 21 (e.g., during a normal driving mode, a regenerative braking mode, an idle charging mode, or a power-assist mode, etc.). A voltage V_inv and a current I_inv output from the power converter 21 may be applied to a resistor R of the load module 110. Thereafter, as a voltage V_prfl and a current I_prfl flow in the load module 110 (e.g., when performing constant power discharge, constant resistance discharge, or constant current discharge, etc.) by a load of the resistor R, the high voltage battery 20 may be discharged (e.g., for a state diagnostic test, a life estimation test, or a manual discharge operation).

In an example, a first discharge mode may be referred to as a constant power (CP) mode. In the CP mode, a first charge voltage may be applied to the resistor R. Herein, the first charge voltage may be a rated voltage for charging, which may be, but is not limited to, 400 V (e.g., a nominal fast-charging level, a mid-level charging standard, or a diagnostic simulation voltage, etc.).

In the first discharge mode, the high voltage battery 20 may be discharged, while a constant voltage, that is, constant power is applied to the resistor R. For example, the processor 130 may transmit a command signal for recognizing that the vehicle EV is connected with the charger via the communication module 120. In other words, because the battery diagnostic apparatus 10 is not the charger, the processor 130 may generate a command signal for commanding the load module 110 to generate a certain voltage (e.g., 350 V, 380 V, or 400 V, etc.) via the communication module 120. Thus, the vehicle EV may recognize that a 400V charger is connected. Simultaneously, the processor 130 may transmit a voltage profile and a current profile for the load module 110 to the EVCC (e.g., a profile including reference values for charging voltage, discharge current, or allowable deviation limits, etc.). Furthermore, the processor 130 may receive data (e.g., a voltage, a current, an SOC, a temperature, or a remaining capacity estimate, etc.) of each of the high voltage battery 20 and the power converter 21 via the communication module 120. Thereafter, the processor 130 may transmit a control signal to the power converter 21 to operate in the first discharge mode via the MCU.

As an example, the processor 130 may set a voltage profile V_EVSEMax not to be greater than an allowable capacity P_Rmax [kW] of the resistor R (e.g., a thermal design limit, a power-handling threshold, or a rated continuous dissipation capacity, etc.). At this time, the magnitude of power P_Rmax corresponding to the voltage profile V_EVSEMax may be smaller than a power P_Rpresent that is transmitted to the load module 110 by the power converter 21. Herein, the power P_Rpresent transmitted by the power converter 21 may meet the following equation. Equation) P_Rpresent = V_invref X V_invref/R At this time, V_invref may be a reference voltage of the circuit of the power converter and R may be a magnitude of the resistor R (e.g., 5 Ω, 10 Ω, or 20 Ω, etc.) of the load module 110. Thus, the processor 130 may calculate a reference voltage V_invref using the above-mentioned equation (e.g., by substituting measured values, by applying a lookup table, or by executing a diagnostic algorithm, etc.). Thereafter, the processor 130 may multiply the reference voltage V_invref by a reciprocal of a constant C_maxtoinv to determine the voltage profile V_EVSEMax. In other words, the voltage profile V_EVSEMax may meet the following equation. Equation) V_EVSEMax = V_invref X 1/C_maxtoinv, where C_maxtoinv may vary depending on the vehicle type (e.g., sedan, SUV, truck, or bus, etc.). For example, the constant C_maxtoinv may be, but is not limited to, 0.9 (e.g., 0.85, 0.9, or 0.95 depending on vehicle characteristics, etc.). Thereafter, the processor 130 may transmit the calculated voltage profile V_EVSEMax to the EVCC. Next, the EVCC may transmit the voltage profile V_EVSEMax to the MCU. The MCU may control the magnitude of the reference voltage V_invref of the power converter 21 to be smaller than the magnitude of the voltage profile V_EVSEMax (e.g., to ensure safe thermal operation, to avoid exceeding current limits, or to maintain stable inverter switching, etc.).

Next, the processor 130 may control an operation of at least one relay to generate a high voltage path for the load module 110. Thus, a voltage may be applied as a rated voltage of 400 V to the resistor R of the load module 110 via the high voltage path (e.g., through a main relay, a safety cut-off relay, or an auxiliary relay, etc.). Furthermore, the voltage may be applied to the resistor R and a current may simultaneously flow in the resistor R. At this time, in the first discharge mode, the voltage applied to the resistor R may be controlled to a constant voltage (e.g., 380 V, 390 V, or 400 V, etc., depending on diagnostic settings). In other words, the power converter 21 may apply the constant voltage to the load module 110 by the control signal of the MCU. Thus, because a constant current flows in the resistor R, the high voltage battery 20 may be discharged while constant power is applied to the load module 110.

In an example, a second discharge mode may be referred to as a constant power (CR) mode. In the CR mode, a second charge voltage may be applied to the resistor R. Herein, the second charge voltage may be, but is not limited to, a rated voltage, 800 V, of the high voltage battery 20 (e.g., a nominal high-voltage level for fast charging, a test voltage for large-capacity packs, or a calibration reference level, etc.).

In the second discharge mode, because the magnitude of the resistor R is controlled to be constant, the high voltage battery 20 may be discharged while a voltage and a current applied to the resistor R are reduced together (e.g., gradually decreasing from 800 V down to 600 V or 400 V depending on discharge progress, etc.). For example, the processor 130 may transmit a command signal for recognizing that the vehicle EV is connected with the charger via the communication module 120 (e.g., through PLC signaling, CAN communication, or Ethernet communication, etc.). In other words, because the battery diagnostic apparatus 10 is not the charger, the processor 130 may generate a command signal for commanding the load module 110 to generate a certain voltage via the communication module 120 (e.g., 750 V, 780 V, or 800 V, etc.). Thus, the vehicle EV may recognize that an 800V charger is connected. Simultaneously, the processor 130 may transmit a voltage profile and a current profile for the load module 110 to the EVCC (e.g., profiles defining maximum allowable ripple, stepwise current reduction, or time-based cutoff thresholds, etc.). Furthermore, the processor 130 may receive data (e.g., a voltage, a current, an SOC, temperature, or internal resistance data, etc.) of each of the high voltage battery 20 and the power converter 21 via the communication module 120. Thereafter, the processor 130 may transmit a control signal to the power converter 21 to operate in the second discharge mode via the MCU.

As an example, the processor 130 may control the power converter 21 to be set to a bypass mode. Herein, the bypass mode may mean that a switching device of the power converter 21 does not perform a switching operation for repeating being short or open and performs a latch operation (e.g., keeping the upper switches closed and the lower switches open, or vice versa, etc.). In other words, because the EVCC recognizes that the 800 V charger is connected, there is no need for the power converter 21 to perform power conversion. Thus, the power converter 21 may be in the bypass mode in which power conversion is not performed (e.g., direct pass-through of battery voltage, diagnostic short-circuit testing, or simplified load simulation, etc.). In the bypass mode, the switching device may continuously maintain a short or open state (e.g., the upper switches latched closed while the lower switches remain open, or vice versa, etc.). Thus, the processor 130 may set the voltage profile V_EVSEMax for operating the power converter 21 in the bypass mode (e.g., 780 V, 790 V, or 800 V reference settings, etc.). Thereafter, the processor 130 may transmit the set voltage profile V_EVSEMax to the EVCC. Next, the EVCC may transmit the voltage profile V_EVSEMax to the MCU (e.g., as a control packet, a frame message, or a lookup reference, etc.). The MCU may control the operation of the switching device of the power converter 21. For example, the switching device (S1 to S3) located on an upper end of the power converter 21 may be controlled to be short and the switching device (S4 to S6) located on a lower end of the power converter 21 may be controlled to be open (e.g., to simulate direct pass-through, to reduce switching losses, or to stabilize current flow, etc.).

Next, the processor 130 may control an operation of at least one relay to generate a high voltage path for the load module 110. Thus, a voltage may be applied as a rated voltage of 800 V to the resistor R of the load module 110 via the high voltage path (e.g., through a main relay, a pre-charge relay, or a contactor, etc.). Furthermore, the voltage may be applied to the resistor R and a current may be simultaneously flow in the resistor R. At this time, because the voltage of the high voltage battery 20 is reduced, the voltage applied to the resistor R may be reduced (e.g., from 800 V gradually down to 700 V, 600 V, or 500 V, etc.). Because the voltage applied to the resistor R decreases more than the voltage profile V_EVSEMax initially set by the processor 130, the EVCC or the VCMS may determine that a voltage deviation occurs in the high voltage battery 20 (e.g., a sudden drop below 750 V, 700 V, or 650 V, etc.). Thus, the EVCC or the VCMS may compulsorily end the connection between the vehicle EV and the battery diagnostic apparatus 10 (e.g., by opening relays, terminating communication, or disabling charging signals, etc.). In this case, the discharging of the high voltage battery 20 may be ended while the battery diagnostic apparatus 10 performs the second discharge mode. The processor 130 may transmit the voltage profile V_EVSEMax, which is varied in real time, to the EVCC via the communication module 120 (e.g., by continuously updating reference values, by adjusting stepwise profiles, or by applying adaptive control logic, etc.), such that the above-mentioned situation does not occur. For example, the processor 130 may reduce and reset the voltage profile V_EVSEMax in response to a decrease in the magnitude of the voltage applied to the resistor R (e.g., reducing by 5 V, 10 V, or 20 V increments, etc.). Thereafter, the processor 130 may transmit the reset voltage profile V_EVSEMax to the EVCC. Thus, the EVCC or the VCMS may determine that a voltage deviation does not occur in the high voltage battery 20.

In the second discharge mode, because the magnitude of the voltage applied to the resistor R is reduced, the magnitude of the current flowing in the resistor R may also be reduced. Thus, while a voltage and a current, which are reduced due to constant resistance of the load module 110, are applied, the high voltage battery 20 may be discharged (e.g., during extended diagnostic cycles, repeated deep discharge, or high-power validation tests, etc.).

In an example, a third discharge mode may be referred to as a constant current (CC) mode. In the CC mode, the first charge voltage may be applied to the resistor R. Herein, the first charge voltage may be a rated voltage for charging, which may be, but is not limited to, 400 V (e.g., 350 V, 380 V, or 400 V depending on pack configuration, etc.).

In the third discharge mode, while the voltage applied to the resistor R is reduced, but a constant current flows in the resistor R, the high voltage battery 20 may be discharged. For example, the processor 130 may transmit a command signal for recognizing that the vehicle EV is connected with the charger via the communication module 120 (e.g., using PLC communication, CAN bus messaging, or Ethernet-based diagnostic signaling, etc.). In other words, because the battery diagnostic apparatus 10 is not the charger, the processor 130 may generate a command signal for commanding the load module 110 to generate a certain voltage via the communication module 120 (e.g., 360 V, 380 V, or 400 V, etc.). Thus, the vehicle EV may recognize that a 400V charger is connected. Simultaneously, the processor 130 may transmit a voltage profile and a current profile for the load module 110 to the EVCC (e.g., profiles specifying constant current values such as 50 A, 75 A, or 100 A, etc.). Furthermore, the processor 130 may receive data (e.g., a voltage, a current, an SOC, temperature, or cell balancing data, etc.) of each of the high voltage battery 20 and the power converter 21 via the communication module 120. Thereafter, the processor 130 may transmit a control signal to the power converter 21 to operate in the third discharge mode via the MCU.

As an example, the processor 130 may set a voltage profile V_EVSEMax not to be greater than an allowable capacity P_Rmax [kW] of the resistor R (e.g., 5 kW, 10 kW, or 20 kW maximum dissipation, etc.). At this time, the magnitude of power P_Rmax corresponding to the voltage profile V_EVSEMax may be smaller than power P_Rpresent transmitted to the load module 110 by the power converter 21. Herein, the power P_Rpresent transmitted by the power converter 21 may meet the following equation. Equation) P_Rpresent = V_invref X V_invref/R At this time, V_invref may be a reference voltage of the circuit of the power converter 21 and R may be a magnitude of the resistor R (e.g., 5 Ω, 8 Ω, or 10 Ω, etc.) of the load module 110. Thus, the processor 130 may calculate a reference voltage V_invref using the above-mentioned equation (e.g., by mathematical computation, by firmware routines, or by real-time simulation, etc.). Thereafter, the processor 130 may multiply the reference voltage V_invref by a reciprocal of a constant C_maxtoinv to determine the voltage profile V_EVSEMax. In other words, the voltage profile V_EVSEMax may meet the following equation. Equation) V_EVSEMax = V_invref X 1/C_maxtoinv, wherein the constant C_maxtoinv may be a unique value according to a type of the vehicle EV (e.g., sedan, SUV, truck, or bus, etc.). For example, the constant C_maxtoinv may be, but is not limited to, 0.9. Thereafter, the processor 130 may transmit the calculated voltage profile V_EVSEMax to the EVCC. Next, the EVCC may transmit the voltage profile V_EVSEMax to the MCU. The MCU may control the magnitude of the reference voltage V_invref of the power converter 21 to be smaller than the magnitude of the voltage profile V_EVSEMax (e.g., to limit power dissipation, to stabilize current control, or to protect semiconductor switches, etc.).

Next, the processor 130 may control an operation of at least one relay to generate a high voltage path for the load module 110. Thus, a voltage may be applied as a rated voltage of 400 V to the resistor R of the load module 110 via the high voltage path (e.g., through a main relay, a pre-charge relay, or a safety contactor, etc.). Furthermore, the voltage may be applied to the resistor R and a current may be simultaneously flow in the resistor R. At this time, because the voltage of the high voltage battery 20 is reduced, the voltage applied to the resistor R may be reduced (e.g., from 400 V gradually down to 380 V, 360 V, or 340 V, etc.). While the current flowing in the power converter 21 increases, the current flowing in the resistor R may not be constant and may increase unexpectedly. The processor 130 may transmit a control signal for varying a reference voltage V_invref applied to the power converter 21 to the EVCC via the communication module 120, such that the above-mentioned situation does not occur. For example, the processor 130 may transmit a control signal for decreasing the magnitude of the reference voltage V_invref to the EVCC (e.g., decreasing by 5 V, 10 V, or 20 V increments, etc.). Thereafter, the EVCC may transmit a control signal to the MCU. The MCU may decrease the magnitude of the reference voltage V_invref of the power converter 21 based on the control signal. Thus, the magnitude of the voltage applied to the power converter 21 may be reduced and the current flowing may also be reduced. In other words, the magnitude of the current flowing in the load module 110 may no longer increase and a constant current may flow (e.g., 50 A, 75 A, or 100 A, etc.). In other words, in the third discharge mode, while the constant current flows in the resistor R, the high voltage battery 20 may be discharged.

As an example, the second discharge mode, that is, the CR mode may be a mode which may operate even if the power converter 21 is not provided in the vehicle (e.g., in architectures where only a direct discharge path is implemented, etc.). The CP mode and the CC mode may be modes capable of operating only if the power converter 21 is provided in the vehicle (e.g., typical EVs with integrated inverters, plug-in hybrid vehicles, or fuel-cell electric vehicles, etc.).

In an example, the processor 130 may diagnose a state of the high voltage battery 20 based on at least one diagnostic mode. Herein, the at least one diagnostic mode may be determined based on a discharge condition, a rest time, and an SOC of the high voltage battery 20, which are preset (e.g., discharge down to 20% SOC, rest for 10 minutes, or perform life evaluation at 50% SOC, etc.). Herein, the at least one diagnostic mode may include a manual discharge mode, a diagnostic preprocessing mode, an SOC monitoring mode, a state diagnostic mode, and a life diagnostic mode.

As an example, in the manual discharge mode, the discharge condition of the high voltage battery 20, the rest time of the high voltage battery 20, an SOC at which discharging ends, or the like may be set in detail by the user (e.g., user selection of cutoff voltage, maximum current limit, or discharge duration, etc.).

In general, if the high voltage battery 20 of the vehicle EV meets a certain SOC, the vehicle EV may be diagnosed. As an example, it is assumed that a current SOC of the vehicle EV needing a diagnosis is greater than a certain SOC. In the diagnostic preprocessing mode, the current SOC of the high voltage battery 20 may be discharged up to the certain SOC to diagnose the vehicle EV (e.g., reducing SOC from 80% to 50% to stabilize testing conditions, etc.). Thus, in the diagnostic preprocessing mode, a state of the high voltage battery 20 during slow charging or fast charging may be diagnosed (e.g., behavior under a 7 kW AC charge, a 50 kW DC fast charge, or a 150 kW ultra-fast charge, etc.).

As an example, in the SOC monitoring mode, a voltage deviation between battery cells of the high voltage battery 20 may be monitored (e.g., differences between maximum and minimum cell voltages, imbalance trends under load, or variations after rest, etc.). In the state diagnostic mode, whether the high voltage battery 20 is abnormal may be diagnosed via data measured while the high voltage battery 20 is discharged (e.g., by analyzing abnormal temperature rise, rapid voltage drops, or irregular current responses, etc.). In the life diagnostic mode, a deterioration degree of the battery cell may be calculated based on a certain SOC change rate and life of the high voltage battery 20 may be determined based on the calculated deterioration degree (e.g., capacity fade of 20%, internal resistance growth, or reduced charge acceptance, etc.).

In an example, the HMI module 140 may be a human machine interface, which may refer to a module in which the user is able to ensure operational visibility of the battery diagnostic apparatus 10 in real time. For example, the HMI module 140 may receive at least one diagnostic mode and at least one discharge mode selected by the user (e.g., manual discharge, preprocessing, or CC discharge, etc.). The HMI module 140 may output the result of diagnosing the high voltage battery 20 to the user (e.g., as text, graphs, or alerts, etc.).

As described above, the system 1 for diagnosing the battery of the vehicle according to the present disclosure may use the inverter provided in the vehicle to improve the reliability of the battery diagnostic apparatus at a low cost (e.g., avoiding the need for a separate high-power test bench, etc.). Furthermore, the system 1 for diagnosing the battery may diagnose whether the vehicle battery is abnormal to prevent a safety accident (e.g., thermal runaway, unexpected shutdown, or over-discharge, etc.). Furthermore, the system 1 for diagnosing the battery is able to diagnose the vehicle battery to improve the accessibility and convenience of the user upon vehicle maintenance (e.g., service center inspection, fleet diagnostics, or on-board user checks, etc.).

In addition, the infrastructure capable of previously diagnosing the battery using the system 1 for diagnosing the battery according to the present disclosure may be expanded (e.g., in charging stations, service garages, or fleet depots, etc.). Thus, service quality for vehicle maintenance may be improved and costs may be reduced to improve customer satisfaction.

FIG. 5 shows an example of a method for diagnosing a battery of a vehicle according to an example of the present disclosure. FIG. 5 shows an example of an operation of a system 1 for diagnosing a battery in FIG. 2.

Referring to FIG. 5, S510 to S550 may be steps of describing an operation in which a system for diagnosing a battery of a vehicle in FIG. 2 discharges a high voltage battery of a vehicle.

In S510, a vehicle and a battery diagnostic apparatus of FIG. 2 may be connected with each other. For example, the battery diagnostic apparatus and the vehicle may be connected with each other via a coupler (e.g., a charge port, diagnostic coupler, CCS connector, CHAdeMO plug, or Type 2 connector, etc.).

In S520, a voltage profile and a current profile for a charge voltage may be transmitted to the vehicle. Herein, the charge voltage may be, but is not limited to, 400 V or 800 V (e.g., depending on vehicle class, pack capacity, or charging standard, etc.). For example, a processor of the battery diagnostic apparatus may transmit a command signal for recognizing that the vehicle is connected with a charger via a communication module (e.g., CAN bus, PLC, or Ethernet-based communication, etc.). Simultaneously, the processor may transmit a voltage profile and a current profile for a load module to an EVCC (e.g., including maximum current limits, stepwise discharge commands, or thermal constraints, etc.).

In S530, an operation of a relay may be controlled such that a high voltage path is generated. For example, the processor may control a main relay of the load module and a relay connected with a resistor to form the high voltage path (e.g., closing the pre-charge relay first, then the main relay, etc.).

In S540, the voltage of the high voltage battery may be applied to the resistor via the high voltage path. For example, the processor may control the charge voltage to be applied to the resistor via the high voltage path (e.g., gradually ramping up from 350 V to 400 V, etc.). In other words, the voltage may be applied from the high voltage battery to the resistor of the load module via the high voltage path.

In S550, the high voltage battery may be discharged based on at least one of a first discharge mode, a second discharge mode, or a third discharge mode. Herein, in the first discharge mode, the high voltage battery may be discharged, while a constant voltage, that is, constant power is applied to the resistor (e.g., maintaining 380 V, 390 V, or 400 V output for a stable diagnostic cycle, etc.). In the second discharge mode, because the magnitude of the resistor is controlled to be constant, the high voltage battery may be discharged while a voltage and a current applied to the resistor are reduced together (e.g., gradual decay characteristic, etc.). In the third discharge mode, the high voltage battery may be discharged, while the voltage applied to the resistor is reduced, but a constant current flows in the resistor (e.g., 50 A, 75 A, or 100 A fixed current, etc.).

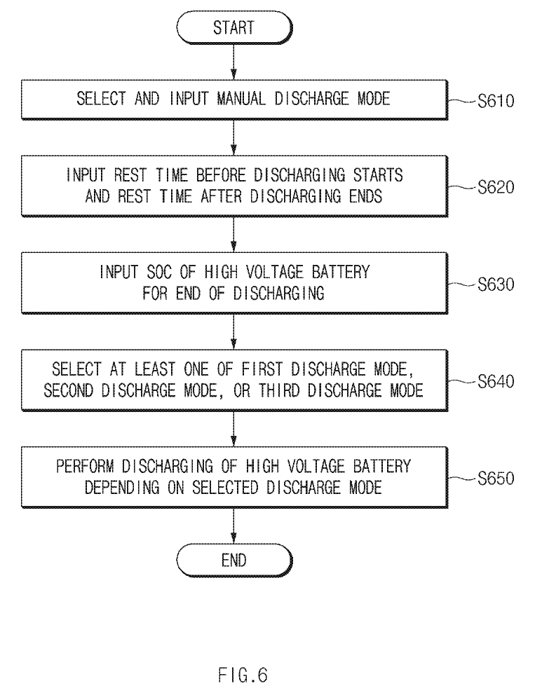

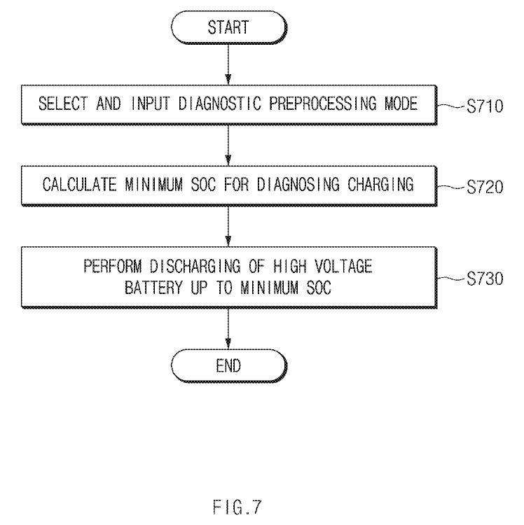

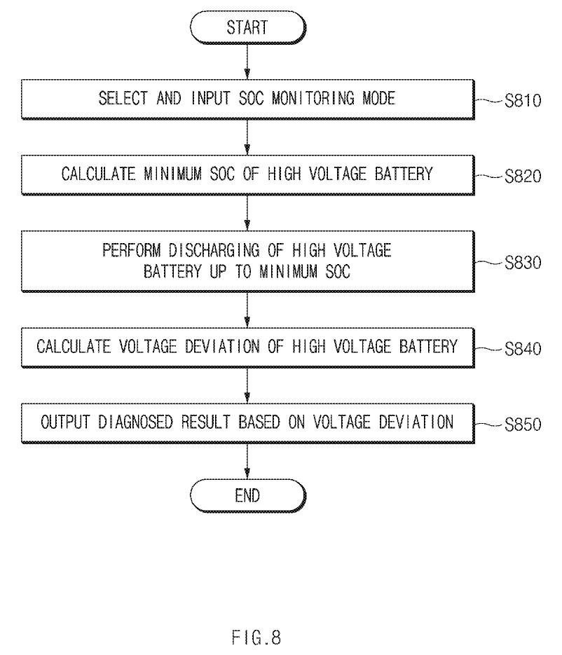

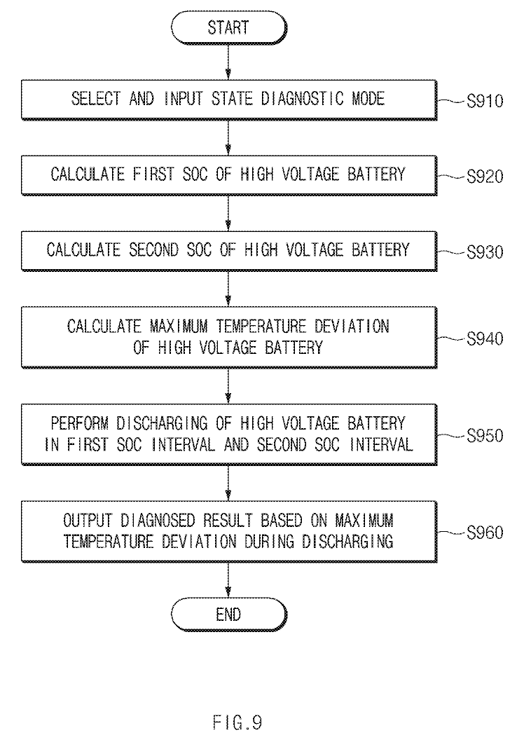

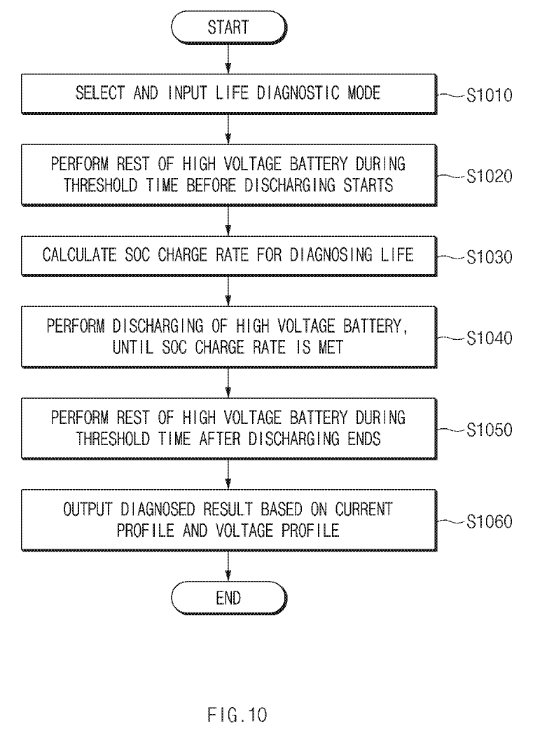

FIG. 6, FIG. 7, FIG. 8, FIG. 9, and FIG. 10 are show an example of at least one diagnostic mode according to an example of the present disclosure.

Referring to FIG. 6, S610 to S650 are a flowchart for describing an operation of a manual discharge mode among at least one diagnostic mode.

In S610, the manual discharge mode may be selected and input by a user. For example, the user may input the manual discharge mode via an HMI module of a battery diagnostic apparatus of FIG. 3 (e.g., touchscreen, physical buttons, or a mobile application interface, etc.). Thus, a processor of the battery diagnostic apparatus may execute the manual discharge mode.

In S620, a rest time before discharging of the high voltage battery starts and a rest time after the discharging ends may be input. For example, the user may input each of the rest time before the discharging starts and the rest time after the discharging ends via the HMI module (e.g., 5 minutes, 10 minutes, or 30 minutes, etc.). Alternatively, the rest time may be a predetermined time.

In S630, an SOC of the high voltage battery for the end of the discharging may be input. For example, the user may input the SOC set as the end of the discharging via the HMI module (e.g., 20%, 30%, or 50% SOC, etc.).

In S640, at least one of the first discharge mode, the second discharge mode, or the third discharge mode may be selected. For example, the user may select at least one of the first discharge mode, the second discharge mode, or the third discharge mode depending on a diagnostic type of the high voltage battery via the HMI module (e.g., CP mode for constant load evaluation, CR mode for long-duration testing, or CC mode for capacity measurement, etc.). Alternatively, the user may select at least one of the first discharge mode, the second discharge mode, or the third discharge mode depending on the selected at least one diagnostic mode. Alternatively, the processor of the battery diagnostic apparatus may select at least one of the first discharge mode, the second discharge mode, or the third discharge mode depending on the at least one diagnostic mode selected by the user (e.g., selecting CP mode for high-power testing, CR mode for resistance-based evaluation, or CC mode for constant-current validation, etc.).

In S650, the discharging of the high voltage battery may be performed according to the selected discharge mode. For example, the processor may control a load module of the battery diagnostic apparatus such that the high voltage battery is discharged according to the at least one of the first discharge mode, the second discharge mode, or the third discharge mode (e.g., CP mode at 400 V, CR mode at 800 V, or CC mode at 100 A, etc.). Simultaneously, the processor may transmit a control signal to an EVCC of a vehicle depending on the at least one of the first discharge mode, the second discharge mode, or the third discharge mode and may transmit a control signal for controlling an operation of a switching device to a power converter of the vehicle (e.g., IGBTs, MOSFETs, or relays, etc.).

Referring to FIG. 7, S710 to S730 are a flowchart for describing an operation of a diagnostic preprocessing mode among the at least one diagnostic mode.

In S710, the diagnostic preprocessing mode may be selected and input by the user. For example, the user may input the diagnostic preprocessing mode via the HMI module of the battery diagnostic apparatus of FIG. 3 (e.g., using menu navigation, quick-select buttons, or a connected device, etc.). Thus, the processor of the battery diagnostic apparatus of FIG. 3 may execute the diagnostic preprocessing mode.

In S720, a minimum SOC for diagnosing charging may be calculated. For example, the processor may calculate the minimum SOC necessary to diagnose charging based on received data of the high voltage battery (e.g., initial SOC, discharge history, or temperature-compensated thresholds, etc.). Alternatively, the processor may receive the minimum SOC from the EVCC of the vehicle.

In S730, the discharging of the high voltage battery may be performed up to the minimum SOC. For example, the processor may transmit a control signal to the load module of the battery diagnostic apparatus and the EVCC such that the discharging of the high voltage battery is performed up to the minimum SOC (e.g., reducing from 80% to 50% SOC before executing further diagnostic steps, etc.).

Referring to FIG. 8, S810 to S850 are a flowchart for describing an operation of an SOC monitoring mode among the at least one diagnostic mode.

In S810, the SOC monitoring mode may be selected and input by the user. For example, the user may input the SOC monitoring mode via the HMI module of the battery diagnostic apparatus of FIG. 3 (e.g., selecting “cell balance check” or “voltage deviation test,” etc.). Thus, the processor of the battery diagnostic apparatus of FIG. 3 may execute the SOC monitoring mode.

In S820, a minimum SOC of the high voltage battery may be calculated. For example, the processor may calculate the minimum SOC of the high voltage battery based on received data of the high voltage battery (e.g., cell voltages, pack current, or accumulated charge data, etc.). Alternatively, the processor may receive the minimum SOC from the EVCC of the vehicle.

In S830, the discharging of the high voltage battery may be performed up to the minimum SOC. For example, the processor may transmit a control signal to the load module of the battery diagnostic apparatus and the EVCC such that the discharging of the high voltage battery is performed up to the minimum SOC (e.g., reducing SOC from 80% to 60%, 70% to 50%, or 50% to 30%, etc.).

In S840, a voltage deviation of the high voltage battery may be calculated. For example, the processor may calculate a voltage deviation while the high voltage battery is discharged. Herein, the voltage deviation may refer to a voltage deviation between battery cells of the high voltage battery (e.g., maximum cell voltage minus minimum cell voltage, or standard deviation across cells, etc.). Alternatively, the BMS, the VCMS, and the EVCC of the vehicle may calculate the voltage deviation, while the high voltage battery is discharged. The processor may receive the calculated voltage deviation.

In S850, the diagnosed result may be output based on the voltage deviation. For example, if the calculated voltage deviation deviates from the normal range (e.g., exceeding a threshold value like 50 mV, 100 mV, or 200 mV, etc.), the processor may diagnose that abnormality occurs in the high voltage battery. Such a diagnosed result may be output via the HMI module (e.g., warning icon, numeric report, or audible alert, etc.).

Referring to FIG. 9, S910 to S960 are a flowchart for describing an operation of a state diagnostic mode among the at least one diagnostic mode.

In S910, the state diagnostic mode may be selected and input by the user. For example, the user may input the state diagnostic mode via the HMI module of the battery diagnostic apparatus of FIG. 3 (e.g., selecting “temperature deviation test” or “state health analysis,” etc.). Thus, the processor of the battery diagnostic apparatus of FIG. 3 may execute the state diagnostic mode.

In S920, a first SOC of the high voltage battery may be calculated. Herein, the first SOC may be an SOC of the high voltage battery, if discharging for diagnosing a state starts. For example, the processor may calculate the first SOC of the high voltage battery based on received data of the high voltage battery (e.g., pack voltage, coulomb counting, or estimated capacity, etc.). Alternatively, the processor may receive the first SOC from the EVCC of the vehicle.

In S930, a second SOC of the high voltage battery may be calculated. Herein, the second SOC may be an SOC of the high voltage battery, if the discharging for diagnosing the state ends. For example, the processor may calculate the second SOC of the high voltage battery based on received data of the high voltage battery (e.g., cell voltage integration, remaining energy estimation, or predictive models, etc.). Alternatively, the processor may receive the second SOC from the EVCC of the vehicle.

In S940, a maximum temperature deviation of the high voltage battery may be calculated. For example, the processor may calculate the maximum temperature deviation of the high voltage battery based on received data (e.g., temperature sensors at cell level, module level, or pack level, etc.) of the high voltage battery. Alternatively, the processor may receive the maximum temperature deviation from the EVCC of the vehicle.

In S950, discharging of the high voltage battery may be performed in a first SOC interval and a second SOC interval. For example, the processor may transmit a control signal to the load module of the battery diagnostic apparatus and the EVCC such that the discharging of the high voltage battery is performed in the first SOC interval and the second SOC interval (e.g., 80%–60% SOC followed by 40%–20% SOC, etc.).

In S960, the diagnosed result may be output based on the maximum temperature deviation during the discharging. For example, the processor may receive the maximum temperature deviation during the discharging from the EVCC. If the maximum temperature deviation deviates from the normal range (e.g., exceeding a threshold value like 5 °C, 10 °C, or 15 °C, etc.), the processor may diagnose that abnormality occurs in the high voltage battery. Such a diagnosed result may be output via the HMI module (e.g., diagnostic report, red status indicator, or maintenance recommendation, etc.).

Referring to FIG. 10, S1010 to S1060 are a flowchart for describing an operation of a life diagnostic mode among the at least one diagnostic mode.

In S1010, the life diagnostic mode may be selected and input by the user. For example, the user may input the life diagnostic mode via the HMI module of the battery diagnostic apparatus of FIG. 3 (e.g., by selecting a “life estimation test,” a “capacity fade check,” or a “long-term health evaluation,” etc.). Thus, the processor of the battery diagnostic apparatus of FIG. 3 may execute the life diagnostic mode.

In S1020, the rest of the high voltage battery may be performed during a threshold time before the discharging starts. Herein, the threshold time may be, but is not limited to, 30 minutes (e.g., 15 minutes, 30 minutes, or 60 minutes depending on thermal stabilization requirements, etc.). For example, the processor may transmit a control signal to the EVCC of the vehicle to perform the rest of the high voltage battery.

In S1030, an SOC charge rate for diagnosing life may be calculated. For example, the processor may calculate the SOC change rate necessary to diagnose the life based on received data of the high voltage battery (e.g., comparing SOC drop per unit discharge time, integrating current over time, or evaluating pack voltage decay, etc.). Alternatively, the processor may receive the SOC charge rate for diagnosing the life from the EVCC.

In S1040, the discharging of the high voltage battery may be performed, until the SOC charge rate is met. For example, the processor may transmit a control signal to the load module of the battery diagnostic apparatus and the EVCC such that the high voltage battery is discharged until the SOC charge rate is met (e.g., 5% SOC drop, 10% SOC drop, or 20% SOC drop, etc.).

In S1050, the rest of the high voltage battery may be performed during a threshold time after the discharging ends. Herein, the threshold time may be, but is not limited to, 30 minutes (e.g., 20 minutes, 30 minutes, or 45 minutes depending on pack temperature, etc.). For example, the processor may transmit a control signal to the EVCC of the vehicle to perform the rest of the high voltage battery.

In S1060, the diagnosed result may be output based on a current profile and a voltage profile of the high voltage battery. For example, the processor may receive a current profile and a voltage profile of the high voltage battery while the discharging and the rest are performed from the EVCC and may calculate a deterioration degree of the high voltage battery based on the current profile and the voltage profile (e.g., estimating capacity fade, identifying increased internal resistance, or detecting abnormal recovery behavior, etc.).

As described above, the method for diagnosing the battery of the vehicle according to the present disclosure may use the inverter provided in the vehicle to improve the reliability of the battery diagnostic apparatus at a low cost (e.g., avoiding external diagnostic equipment, etc.). Furthermore, the method for diagnosing the battery may diagnose whether the vehicle battery is abnormal to prevent a safety accident (e.g., overheating, fire hazard, or sudden loss of power, etc.). Furthermore, the method for diagnosing the battery is able to diagnose the vehicle battery at a low cost to improve the accessibility and convenience of the user upon vehicle maintenance (e.g., during scheduled service, pre-sale inspections, or fleet health checks, etc.).

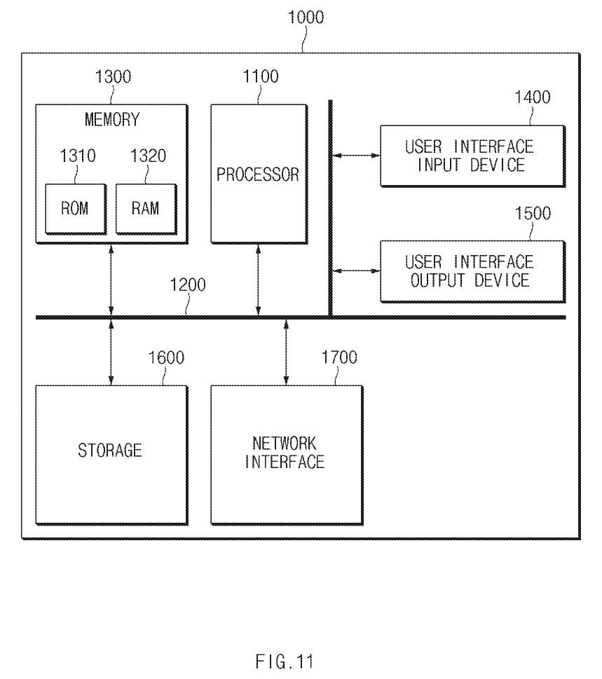

FIG. 11 shows an example of a computing system 1000 according to an example of the present disclosure.

Referring to FIG. 11, a computing system 1000 may include at least one processor 1100, a memory 1300, a user interface input device 1400, a user interface output device 1500, a storage 1600, and a network interface 1700, which are connected with each other via a bus 1200 (e.g., PCI bus, system-on-chip interconnect, or high-speed serial bus, etc.).

The processor 1100 may be a central processing unit (CPU) or a semiconductor device that processes instructions stored in the memory 1300 and/or the storage 1600 (e.g., GPU, DSP, or microcontroller, etc.). The memory 1300 and the storage 1600 may include various types of volatile or non-volatile storage media. For example, the memory 1300 may include a read only memory (ROM) 1310 and a random access memory (RAM) 1320 (e.g., DRAM, SRAM, or SDRAM, etc.).

Accordingly, the operations of the method or algorithm described in connection with the examples disclosed in the specification may be directly implemented with a hardware module, a software module, or a combination of the hardware module and the software module, which is executed by the processor 1100. The software module may reside on a storage medium (i.e., the memory 1300 and/or the storage 1600) such as a RAM, a flash memory, a ROM, an EPROM, an EEPROM, a register, a hard disc, a removable disk, a solid-state drive (SSD), or an optical medium (e.g., DVD or Blu-ray, etc.) or a CD-ROM.

The exemplary storage medium may be coupled to the processor 1100. The processor 1100 may read out information from the storage medium and may write information in the storage medium. Alternatively, the storage medium may be integrated with the processor 1100. The processor and the storage medium may reside in an application specific integrated circuit (ASIC). The ASIC may reside within a user terminal (e.g., smartphone, vehicle infotainment system, or wearable device, etc.). In another case, the processor and the storage medium may reside in the user terminal as separate components.

The user interface input device 1400 may include an input device that receives a user input (e.g., keyboard, touchscreen, microphone, steering wheel button, or gesture sensor, etc.).

The user interface output device 1500 may include a display for displaying various pieces of information associated with driving of the vehicle and/or a function of the vehicle and a speaker for outputting various sounds associated with the driving of the vehicle and/or the function of the vehicle (e.g., warning chimes, navigation prompts, or multimedia playback, etc.).

Herein, the display provides a user interface for allowing a passenger and the vehicle to interact with each other. For example, the display may include a liquid crystal display (LCD) panel and/or a light emitting diode (LED) (e.g., OLED, AMOLED, or microLED, etc.).

The display may provide the user with various pieces of information based on a control signal of the processor 1100. For example, the display may be provided in a center fascia which is a central area of a dashboard in the vehicle. The display may be a component of a head unit and may be a component of a navigation device provided independently of the head unit. Herein, the head unit may process and output an audio signal and a video signal and may perform a navigation function. Thus, the head unit may be referred to as an audio video navigation (AVN) device. For example, the display may display a route guidance screen, that is, a screen necessary to perform the navigation function. Furthermore, the display may further display a screen necessary to perform an audio function, a video function, or a dialing function, or vehicle diagnostics (e.g., SOC status, maintenance alerts, or efficiency data, etc.).

The network interface 1700 may include a long range communication module and/or a short range communication module, which transmit(s) and receive(s) data with an external device (e.g., a server or a user terminal). For example, the network interface 1700 may refer to a communication module capable of performing wireless Internet communication, such as a wireless LAN (WLAN), wireless broadband (Wibro), wireless-fidelity (Wi-Fi), world interoperability for microwave access (WiMAX), or high speed downlink packet access (HSDPA) (e.g., LTE, 5G NR, Bluetooth, or NFC, etc.).

For example, the user may enter a destination via the user interface input device 1400 (e.g., voice command, touch input, or keypad entry, etc.) and the user interface output device 1500 may provide a route for reaching the destination (e.g., visual navigation map, step-by-step voice guidance, or haptic feedback, etc.).

According to an example of the present disclosure, a system for diagnosing a battery of a vehicle may include a high voltage battery installed in the vehicle to supply power, a power converter installed in the vehicle to convert direct current (DC) power supplied to the high voltage battery, and a battery diagnostic apparatus connected with the power converter to discharge the high voltage battery and diagnose a state of the high voltage battery.

In an example, the battery diagnostic apparatus may include a load module including at least one resistor and at least one relay and connected with the power converter to discharge the high voltage battery based on at least one discharge mode, a communication module that transmits and receive data of the high voltage battery, and a processor that controls operations of the power converter and the load module and diagnoses the state of the high voltage battery based on at least one diagnostic mode.

In an example, the battery diagnostic apparatus may further include a human machine interface (HMI) module that receives the at least one diagnostic mode and the at least one discharge mode selected by a user and outputs the result of diagnosing the high voltage battery.

In an example, the power converter may include a switching device including at least one switching element and at least one diode. The switching device may operate based on the at least one discharge mode.

In an example, the processor may transmit a voltage profile and a current profile for a charge voltage to the vehicle, if the vehicle is connected with the battery diagnostic apparatus.

In an example, the processor may control an operation of the at least one relay to generate a high voltage path for the load module and may control the charge voltage to be applied to the resistor via the high voltage path.

In an example, a voltage may be applied from the high voltage battery to the resistor of the load module via the high voltage path. The high voltage battery may be discharged.

In an example, the at least one discharge mode may include a first discharge mode in which a first charge voltage is applied to the resistor and the high voltage battery is discharged while a constant voltage is applied to the resistor, a second discharge mode in which a second charge voltage is applied to the resistor and the high voltage battery is discharged while a current flowing in the resistor is reduced, and a third discharge mode in which the first charge voltage is applied to the resistor and the high voltage battery is discharged while the voltage applied to the resistor is reduced, but a constant current flows in the resistor. The first charge voltage may be smaller in magnitude than the second charge voltage.

In an example, the second charge voltage may be a rated voltage of the high voltage battery. The second discharge mode may be controlled by an operation of the switching device of the power converter.

In an example, the at least one diagnostic mode may be determined based on a discharge condition, a rest time, and a state of charge (SOC) of the high voltage battery, the discharge condition, the rest time, and the SOC being preset.

According to another example of the present disclosure, a method for diagnosing a battery of a vehicle may include being installed, by a high voltage battery, in the vehicle to supply power, being installed, by a power converter, in the vehicle to convert direct current (DC) power supplied to the high voltage battery, and being connected, by a processor, with the power converter to discharge the high voltage battery and diagnose a state of the high voltage battery.

In another example, the diagnosing of the state of the high voltage battery may include including, by a load module, at least one resistor and at least one relay, being connected, by the load module, with the power converter to discharge the high voltage battery based on at least one discharge mode, transmitting and receiving, by a communication module, data of the high voltage battery, and controlling, by a processor, operations of the power converter and the load module and diagnosing, by the processor, the state of the high voltage battery based on at least one diagnostic mode.

In another example, the diagnosing of the state of the high voltage battery may further include receiving, by an HMI module, the at least one diagnostic mode and the at least one discharge mode selected by a user and outputting, by the HMI module, the result of diagnosing the high voltage battery.

In another example, the power converter may include a switching device including at least one switching element and at least one diode. The diagnosing of the state of the high voltage battery may further include operating the switching device based on the at least one discharge mode.

In another example, the diagnosing of the state of the high voltage battery may further include transmitting a voltage profile and a current profile for a charge voltage to the vehicle.

In another example, the diagnosing of the state of the high voltage battery may further include controlling an operation of the at least one relay to generate a high voltage path for the load module and controlling the charge voltage to be applied to the resistor via the high voltage path.

In another example, the diagnosing of the state of the high voltage battery may further include applying a voltage of the high voltage battery to the resistor of the load module via the high voltage path and discharging the high voltage battery.

In another example, the at least one discharge mode may include a first discharge mode in which a first charge voltage is applied to the resistor and the high voltage battery is discharged while a constant voltage is applied to the resistor, a second discharge mode in which a second charge voltage is applied to the resistor and the high voltage battery is discharged while a current flowing in the resistor is reduced, and a third discharge mode in which the first charge voltage is applied to the resistor and the high voltage battery is discharged while the voltage applied to the resistor is reduced, but a constant current flows in the resistor. The first charge voltage may be smaller in magnitude than the second charge voltage.

In another example, the second charge voltage may be a rated voltage of the high voltage battery. The second discharge mode may be controlled by an operation of the switching device of the power converter.

In another example, the at least one diagnostic mode may be determined based on a discharge condition, a rest time, and a state of charge (SOC) of the high voltage battery, the discharge condition, the rest time, and the SOC being preset.

The present technology may use an inverter provided in a vehicle to improve reliability of a battery diagnostic apparatus at a low cost.

Furthermore, the present technology may diagnose whether the battery of the vehicle is abnormal in advance to prevent a safety accident.

Furthermore, the present technology may diagnose the battery of the vehicle at a low cost to improve accessibility and convenience of the user upon vehicle maintenance.

In addition, various effects ascertained directly or indirectly through the present disclosure may be provided.

Hereinabove, although the present disclosure has been described with reference to examples and the accompanying drawings, the present disclosure is not limited thereto, but may be variously modified and altered by those skilled in the art to which the present disclosure pertains without departing from the spirit and scope of the present disclosure claimed in the following claims.

Therefore, examples of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

What is claimed is:

1. A system for a vehicle, the system comprising:
a battery installed in the vehicle and configured to supply power to the vehicle;
a power converter installed in the vehicle and configured to convert direct current (DC) power of the battery to first converted power for at least one operation of a vehicle part of the vehicle, and second converted power for diagnosing the battery; and
a battery diagnostic apparatus coupled to the power converter and configured to:
discharge, via the second converted power being transferred to the battery diagnostic apparatus, the battery,
determine a state of the battery based on data associated with the battery obtained during the discharge, and
output, based on the determined state of the battery, a signal indicating a diagnosed state of the battery.

2. The system of claim 1, wherein the battery diagnostic apparatus comprises:
a load, when coupled to the power converter, configured to discharge the battery based on at least one discharge mode, wherein the load comprises at least one resistor and at least one relay;
a communication interface configured to transmit and receive data associated with the battery; and
a processor circuit configured to control operations of the power converter and the load and determine the state of the battery based on at least one diagnostic mode.

3. The system of claim 2, wherein the battery diagnostic apparatus comprises:
a human machine interface (HMI) configured to:
receive the at least one diagnostic mode and the at least one discharge mode, wherein the at least one diagnostic mode and the at least one discharge mode are configured to be selected by a user, and
output the determined state of the battery.

4. The system of claim 3, wherein the power converter comprises:
at least one switch and at least one diode, and
wherein the at least one switch and the at least one diode are configured to operate the power converter based on the at least one discharge mode.

5. The system of claim 4, wherein the processor circuit is configured to:
transmit a voltage profile and a current profile for a charge voltage to the vehicle, based on the vehicle being coupled with the battery diagnostic apparatus.

6. The system of claim 5, wherein the processor circuit is configured to:
control an operation of the at least one relay to set a current flow path for the load, and control application of the charge voltage to the at least one resistor via the current flow path.

7. The system of claim 6, wherein the charge voltage is applied from the battery to the at least one resistor via the current flow path, and
wherein the battery is discharged via the at least one resistor.

8. The system of claim 7, wherein the at least one discharge mode comprises:
a first discharge mode in which a first charge voltage is applied to the at least one resistor and the battery is discharged while a constant voltage is applied to the at least one resistor;
a second discharge mode in which a second charge voltage is applied to the at least one resistor and the battery is discharged while a current flowing in the at least one resistor is reduced; and
a third discharge mode in which the first charge voltage is applied to the at least one resistor and the battery is discharged while the first charge voltage applied to the at least one resistor is reduced, and a constant current flows in the at least one resistor, and wherein the first charge voltage is less than the second charge voltage.

9. The system of claim 8, wherein the second charge voltage is a rated voltage of the battery, and
wherein the second discharge mode is controlled by an operation of the at least one switch and the at least one diode.

10. The system of claim 9, wherein the at least one diagnostic mode is determined based on:
a preset discharge condition of the battery,
a preset rest time of the battery, and
a preset state of charge (SOC) of the battery.

11. A method performed by a system for a vehicle, the method comprising:
supplying, from a battery via a power converter installed in the vehicle, first power to the vehicle;
based on coupling of a battery diagnostic apparatus to the power converter, converting, by the power converter installed in the vehicle, direct current (DC) power of the battery to second power for diagnosing the battery;
discharging, via the power converter, the battery using the second power;
determining a state of the battery based on data associated with the battery obtained during the discharging; and
outputting, based on the determined state of the battery, a signal indicating a diagnosed state of the battery.

12. The method of claim 11, wherein the determining of the state of the battery comprises:
via a load of the battery diagnostic apparatus, when the load is coupled to the power converter and based on at least one discharge mode, discharging the battery, wherein the load comprises at least one resistor and at least one relay;
transmitting and receiving, via a communication interface of the system, data associated with the battery;
controlling operations of the power converter and the load; and
determining the state of the battery based on at least one diagnostic mode.

13. The method of claim 12, wherein the determining of the state of the battery comprises:
receiving, by a human machine interface (HMI) of the system, the at least one diagnostic mode and the at least one discharge mode, wherein the at least one diagnostic mode and the at least one discharge mode are configured to be selected by a user; and
outputting, by the HMI, the determined state of the battery.

14. A battery diagnostic apparatus for a vehicle, the battery diagnostic apparatus comprising:
a load configured to be coupled with a battery of the vehicle through a power converter installed in the vehicle, the load being configured to discharge the battery under at least one of a constant power mode, a constant resistance mode, or a constant current mode;
a communication interface configured to exchange data with the vehicle during the discharge of the battery, wherein the data comprises at least one of voltage of the battery, current of the battery, temperature of the battery, or state of charge of the battery;
a charge port configured to connect the battery diagnostic apparatus to the vehicle and provide, during diagnosis, a discharge path for the battery;
a human machine interface configured to receive a selection of at least one diagnostic mode, wherein the at least one diagnostic mode comprises a manual discharge mode, a preprocessing mode, a state-of-charge monitoring mode, a state diagnostic mode, or a life diagnostic mode; and
a processor circuit configured to:
control the power converter and the load to discharge the battery based on the received selection of the at least one diagnostic mode, and
output, based on processing the data, diagnostic results indicating whether the battery is abnormal and a current state of the battery.

15. The battery diagnostic apparatus of claim 14, wherein the processor circuit is configured to, in the constant power mode, control the load by applying a constant voltage to the load during discharge of the battery.

16. The battery diagnostic apparatus of claim 14, wherein the processor circuit is configured to, in the state-of-charge monitoring mode,
identify a voltage deviation among battery cells of the battery and
determine, based on the identified voltage deviation, the diagnostic results.

17. The battery diagnostic apparatus of claim 14, wherein the processor circuit is configured to, in the preprocessing mode, discharge the battery to a preset state of charge of the battery before executing another one of the at least one diagnostic mode.

18. The battery diagnostic apparatus of claim 14, wherein the processor circuit is configured to, in the life diagnostic mode, determine a deterioration degree of the battery based on a change rate of the state of charge during the discharge.

19. The battery diagnostic apparatus of claim 14, wherein the processor circuit is configured to, in the manual discharge mode, control the discharge of the battery based on discharge conditions and rest times input by a user via the human machine interface.

20. The battery diagnostic apparatus of claim 14, wherein the processor circuit is configured to, in the state diagnostic mode, determine whether the battery is abnormal based on a temperature deviation of the battery during the discharge.
